(19) United States
(12) Patent Application Publication
(10) Pub. No.: US 2026/0255650 A1
(43) Pub. Date: Aug. 27, 2026

(54) SEMICONDUCTOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Shih-Hao LIN, Hsinchu City (TW); Yu-Bey WU, Hsinchu City (TW); Ping-Wei WANG, Hsinchu City (TW)

(73) Assignee: TAIWAN SEMICONDUCTOR MANUFACTURING COMPANY, LTD., Hsinchu (TW)

(21) Appl. No.: 19/061,713

(22) Filed: Feb. 24, 2025

(51) Int. Cl. H10D 64/23; H10D 30/00; H10D 30/01

(52) U.S. Cl. CPC H10D 64/254; H10D 30/0198; H10D 30/501

(57) ABSTRACT

A device includes a channel structure, a gate structure, a first source/drain epitaxial structure, a second source/drain epitaxial structure, and a backside source/drain contact. The gate structure covers the channel structure. The first source/drain epitaxial structure and the second source/drain epitaxial structure are on opposite sides of the gate structure and connected to the channel structure. The backside source/drain contact is under and connected to the first source/drain epitaxial structure. The backside source/drain contact includes a first portion embedded in the first source/drain epitaxial structure and a second portion connected to the first portion. A sidewall of the first portion and a sidewall of the second portion have different slopes.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10B illustrate a method for manufacturing a semiconductor device (or an integrated circuit structure) at various stages in accordance with some embodiments of the present disclosure.

FIG. 11 is a graph of a dopant concentration of the source/drain epitaxial structure in a depth direction.

FIG. 12 is a dopant concentration distribution of the source/drain epitaxial structure.

FIGS. 13-16B are cross-sectional view of an integrated circuit structure (or a semiconductor device) in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to methods of forming semiconductor devices. More particularly, some embodiments of the present disclosure are related to semiconductor devices including at least one backside source/drain contact shaped like a funnel or a multi-stage tapered pillar, featuring successive reductions in diameter or width at distinct stages along its length. The funnel-shaped backside source/drain contact improves the current crowding issues between the backside source/drain contact and the channel structures, and also improves electrical short issues between the backside source/drain contact and the gate structure.

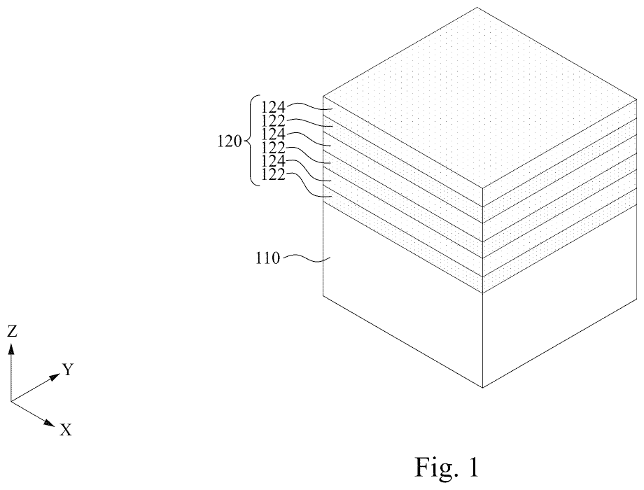

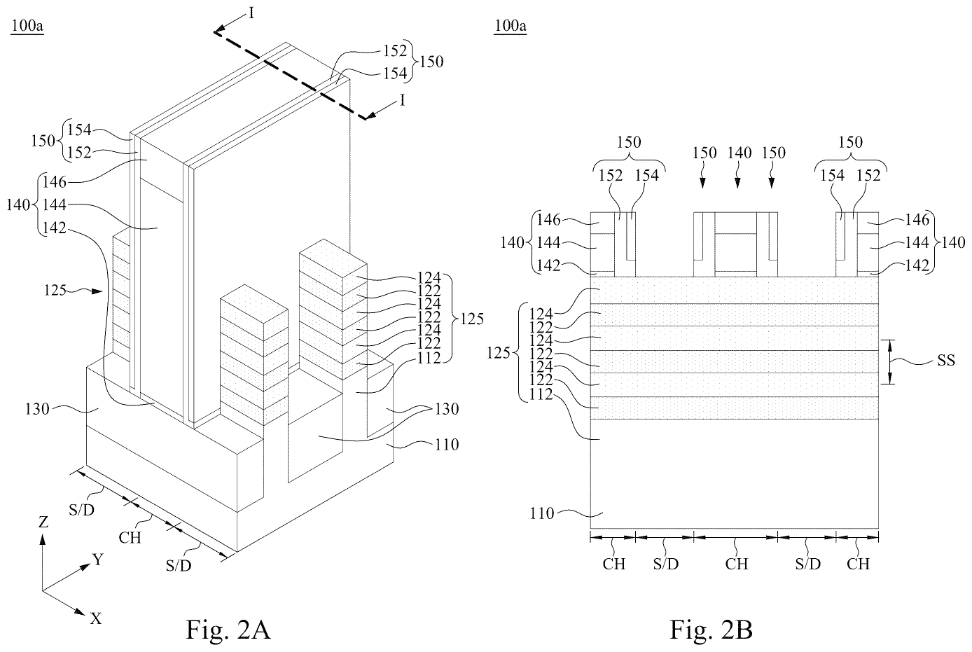

FIGS. 1-10B illustrate a method for manufacturing a semiconductor device (or an integrated circuit structure) 100a at various stages in accordance with some embodiments of the present disclosure. In addition to the semiconductor device 100a, FIGS. 1-2A depict X-axis, Y-axis, and Z-axis directions. In some embodiments, the semiconductor device shown in FIGS. 1-10B may be intermediate devices fabricated during processing of an integrated circuit (IC), or a portion thereof, that may include static random access memory (SRAM), logic circuits, passive components, such as resistors, capacitors, and inductors, and/or active components, such as p-type FETs (PFETs), n-type FETs (NFETs), multi-gate FETs, MOSFETs, complementary metal-oxide semiconductor (CMOS) transistors, bipolar transistors, high voltage transistors, high frequency transistors, other memory cells, and combinations thereof.

Referring to FIG. 1, a semiconductor stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method.

The semiconductor stack 120 includes semiconductor layers 122 of a first composition interposed by semiconductor layers 124 of a second composition arranged in a stacking direction (Z-axis in this case). The first and second compositions are different. In some embodiments, the semiconductor layers 122 are SiGe and the semiconductor layers 124 are silicon (Si). However, other embodiments are possible including those that provide for a first composition and a second composition having different etch selectivity. In some embodiments, the semiconductor layers 124 are spaced from each other by a pitch (or sheet spacing) SS, which is denoted in FIG. 2B.

The semiconductor layers 124 or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the semiconductor layers 124 to define a channel or channels of a device is further discussed below.

It is noted that three layers of the semiconductor layers 122 and three layers of the semiconductor layers 124 are arranged as illustrated in FIG. 1, which is for illustrative purposes only and not intended to be limiting beyond what is specifically recited in the claims. It can be appreciated that any number of semiconductor layers can be formed in the semiconductor stack 120; the number of layers depending on the desired number of channels regions for the transistor. In some embodiments, the number of each of the semiconductor layers 122 and 124 is between 2 and 10.

As described in more detail below, the semiconductor layers 124 may serve as channel region(s) for a subsequently-formed semiconductor device and the thickness is chosen based on device performance considerations. The semiconductor layers 122 in channel region(s) may eventually be removed and serve to define a vertical distance between adjacent channel region(s) for a subsequently-formed multi-gate device and the thickness is chosen based on device performance considerations. Accordingly, the semiconductor layers 122 may also be referred to as sacrificial layers, and the semiconductor layers 124 may also be referred to as channel structures.

By way of example, epitaxial growth of the layers of the semiconductor stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the semiconductor layers 124 include the same material as the substrate 110. In some embodiments, the semiconductor layers 122 and 124 include a different material than the substrate 110. As stated above, in at least some examples, the semiconductor layers 122 include an epitaxially grown silicon germanium (SiGe) layer and the semiconductor layers 124 include an epitaxially grown silicon (Si) layer. Alternatively, in some embodiments, either of the semiconductor layers 122 and 124 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the semiconductor layers 122 and 124 may be chosen based on providing differing oxidation and/or etching selectivity properties.

Reference is made to FIGS. 2A and 2B, where FIG. 2B is a cross-sectional view taken along line I-I of FIG. 2A. At least one fin structure 125 extending from the substrate 110 is formed. In various embodiments, the fin structure 125 includes a semiconductor base portion 112 formed from the substrate 110 and portions of each of the semiconductor layers of the semiconductor stack 120 including the semiconductor layers 122 and 124. The fin structure 125 may be fabricated using suitable processes including double-patterning or multi-patterning processes.

Next, isolation structures 130 are formed to surround the fin structure 125. The isolation structures 130 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 130 may also include a dielectric material over the liner oxide, and the dielectric material may be formed using flowable chemical vapor deposition (FCVD), spin-on coating, or the like.

The isolation structures 130 are then planarized, and the top surfaces of the fin structure 125 are exposed. Subsequently, the isolation structures 130 are recessed, so that the top portions of the fin structure 125 protrude higher than the top surfaces of the neighboring isolation structures 130. The etching may be performed using a dry etching process or a wet etch process.

At least one dummy gate structure 140 is formed over the substrate 110 and across the fin structure 125. It is noted that in the first cut (line I-I), three dummy gate structures 140 are illustrated in FIG. 2B to clearly show the details of the semiconductor device 100a. The portions of the fin structures 125 underlying the dummy gate structures 140 may be referred to as channel regions CH. The dummy gate structures 140 may also define source/drain regions S/D of the fin structures 125, for example, the regions of the fin structures 125 adjacent and on opposite sides of the channel regions CH.

Dummy gate formation operation forms a dummy gate dielectric layer, a dummy gate electrode layer and a hard mask which may include multiple layers (e.g., a nitride layer and an oxide layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, a dummy gate structure 140 including a dummy gate dielectric layer 142, a dummy gate electrode layer 144 and a hard mask 146 (e.g., a nitride layer and an oxide layer) is formed.

After the formation of the dummy gate structures 140 is completed, gate spacers 150 are formed on opposite sidewalls of the dummy gate structures 140. For example, a spacer material layer is deposited on the substrate 110. The spacer material layer may be a conformal layer that is subsequently etched back to form gate sidewall spacers. In the illustrated embodiments, a spacer material layer is disposed conformally on top and sidewalls of the dummy gate structures 140. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer 152 and a second spacer layer 154 formed over the first spacer layer 152. By way of example, the spacer material layer may be formed by depositing a dielectric material over the dummy gate structures 140 and the fin structures 125 using suitable deposition processes. An anisotropic etching process is then performed on the deposited spacer material layer to expose portions of the fin structures 125 not covered by the dummy gate structures 140 (e.g., over the source/drain regions S/D of the fin structures 125). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 150, for the sake of simplicity.

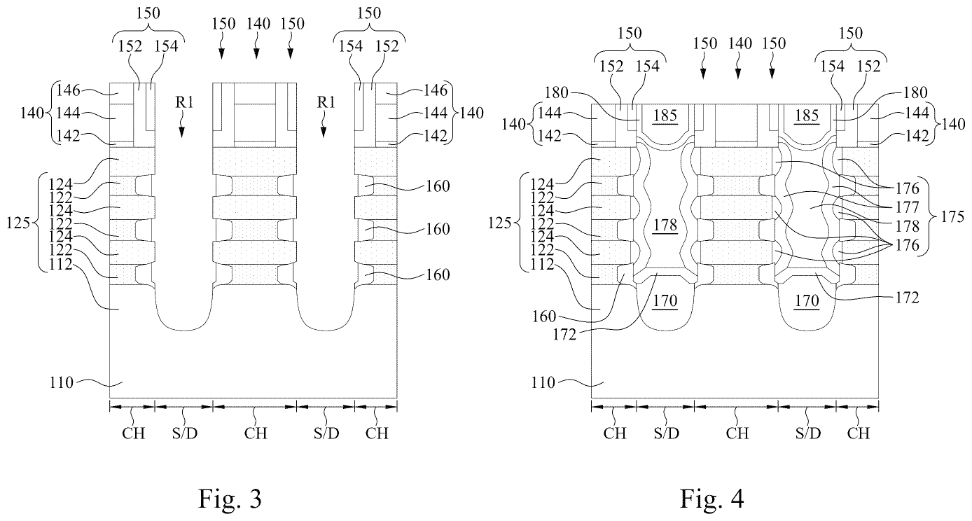

Reference is made to FIG. 3. Exposed portions of the fin structure 125 that extend laterally beyond the gate spacers 150 (e.g., in source/drain regions S/D of the fin structure 125) are etched by using, for example, an anisotropic etching process that uses the dummy gate structures 140 and the gate spacers 150 as an etch mask, resulting in recesses R1 into the fin structure 125. After the anisotropic etching, end surfaces of the semiconductor layers 122 and 124 and respective outermost sidewalls of the gate spacers 150 are substantially coterminous, due to the anisotropic etching. In some embodiments, the anisotropic etching may be performed by a dry chemical etch with a plasma source and a reaction gas.

The semiconductor layers 122 are then laterally or horizontally recessed by using suitable etch techniques, resulting in lateral recesses each vertically between corresponding semiconductor layers 124. These operations may be performed by using selective etching processes. In some embodiments, the selective dry etching etches SiGe at a faster etch rate than it etches Si.

Subsequently, inner dielectric spacers 160 are filled in the recesses, respectively. For example, spacer material layers are formed and then trimmed to fill the recesses. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

Reference is made to FIG. 4. Bottom semiconductor structures 170 are formed in the recesses R1. In some embodiments, semiconductor materials are deposited on the semiconductor base portion 112 to form the bottom semiconductor structures 170. The semiconductor materials include a single element semiconductor material, such as germanium (Ge) or silicon (Si), compound semiconductor materials, such as gallium arsenide (GaAs) or aluminum gallium arsenide (AlGaAs), or a semiconductor alloy, such as silicon germanium (SiGe) or gallium arsenide phosphide (GaAsP). The bottom semiconductor structures 170 have suitable crystallographic orientations (e.g., a (100), (110), or (111) crystallographic orientation). The epitaxial processes include CVD deposition techniques (e.g., vapor-phase epitaxy (VPE) and/or ultra-high vacuum CVD (UHV-CVD)), molecular beam epitaxy, and/or other suitable processes. In some embodiments, the bottom semiconductor structures 170 are intrinsic. That is, the bottom semiconductor structures 170 are undoped. The undoped bottom semiconductor structures 170 are benefit for reducing current leakage from the following formed source/drain epitaxial structures 175 to the substrate 110. The bottom semiconductor structures 170 are spaced apart from the semiconductor layers 124.

Subsequently, dielectric layers 172 are formed in the recesses R1 and covers the bottom semiconductor structures 170. In some embodiments, the dielectric layers 172 include silicon nitride layers, silicon oxide layers, silicon oxynitride layers, and/or other suitable materials.

Next, source/drain epitaxial structures 175 are formed in the recesses R1 and over the dielectric layers 172. In some embodiments, each of the source/drain epitaxial structures 175 includes first semiconductor portions 176 connected to the semiconductor layers 124, second semiconductor portions 177 covering the first semiconductor portions 176 and the inner dielectric spacers 160, and a third semiconductor portion 178 connected to the second semiconductor portions 177. The first semiconductor portions 176, the second semiconductor portions 177, and the third semiconductor portion 178 may be formed of different semiconductor materials and may be doped to different impurities. For example, the first semiconductor portions 176 and the second semiconductor portions 177 are made of SiAs or other suitable materials, and the third semiconductor portion 178 is made of SiP or other suitable materials. In some other embodiments, the first semiconductor portions 176 and the second semiconductor portions 177 are made of SiB, SiGe, SiGeB or other suitable materials, and the third semiconductor portion 178 is made of SiB, SiGe, SiGeB or other suitable materials. In some embodiments, a dopant concentration of the third semiconductor portion 178 is higher than a dopant concentration of the second semiconductor portions 177 and/or a dopant concentration of the first semiconductor portions 176.

The source/drain epitaxial structures 175 are on opposite sides and connected to the semiconductor layers 124. The source/drain epitaxial structures 175 may be formed by performing an epitaxial growth process that provides epitaxial materials in the recesses R1. In some embodiments, the lattice constants of the source/drain epitaxial structures 175 are different from the lattice constant of the semiconductor layers 124, so that the semiconductor layers 124 can be strained or stressed by the source/drain epitaxial structures 175 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor layers 124.

In some embodiments, the source/drain epitaxial structures 175 may include Ge, Si, GaAs, AlGaAs, SiGe, GaAsP, SiP, SiAs, or other suitable material. The source/drain epitaxial structures 175 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 175 are not in-situ doped, an implantation process (i.e., a junction implant process) is performed to dope the source/drain epitaxial structures 175.

A contact etch stop layer (CESL) 180 and an interlayer dielectric (ILD) layer 185 are sequentially formed over the source/drain epitaxial structures 175 and fill the recesses R1. In some examples, the CESL 180 includes a silicon nitride layer, a silicon oxide layer, a silicon oxynitride layer, and/or other suitable materials. The CESL 180 may be formed by plasma-enhanced chemical vapor deposition (PECVD) process and/or other suitable deposition or oxidation processes. The ILD layer 185 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 180. The ILD layer 185 may be deposited by a PECVD process or other suitable deposition technique.

In some examples, after depositing the ILD layer 185, a planarization process may be performed to remove excessive materials of the ILD layer 185. For example, a planarization process includes a chemical mechanical planarization (CMP) process which removes portions of the ILD layer 185 and the CESL 180 overlying the dummy gate structures 140 and planarizes a top surface of the semiconductor device 100a. In some embodiments, the CMP process also removes hard masks 146 (as shown in FIG. 3) and exposes the dummy gate electrode layers 144.

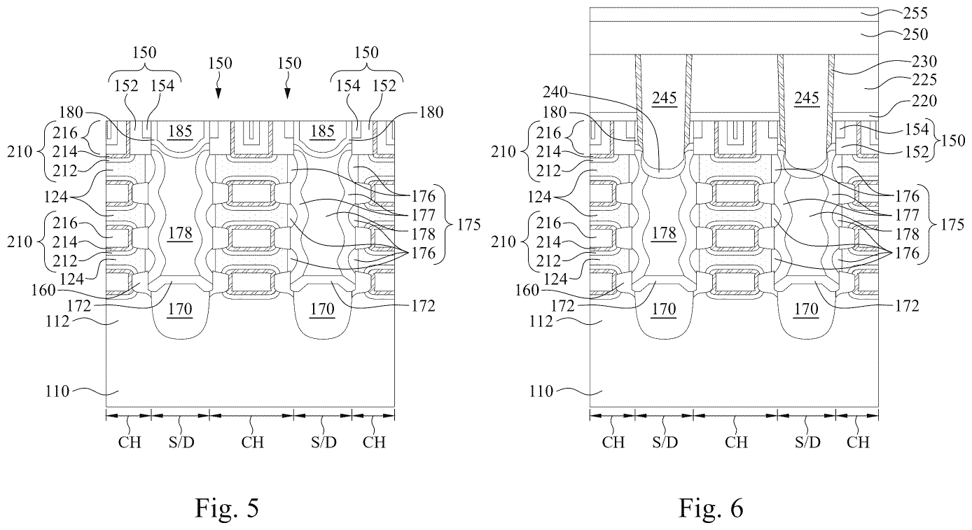

Reference is made to FIGS. 4 and 5. Thereafter, a gate replacement process is performed. Specifically, the dummy gate electrode layer 144 and the dummy gate dielectric layer 142 are removed, and then the semiconductor layers (i.e., sacrificial layers) 122 are removed. In some embodiments, the dummy gate electrode layers 144 and the dummy gate dielectric layer 142 are removed by using a selective etching process (e.g., selective dry etching, selective wet etching, or combinations thereof) that etches the materials in dummy gate electrode layers 144 and the dummy gate dielectric layer 142 at a faster etch rate than it etches other materials (e.g., the gate spacers 150), thus resulting in gate trenches between the gate spacers 150, with the semiconductor layers 122 exposed in the gate trenches. Subsequently, the semiconductor layers 122 in the gate trenches are removed by using another selective etching process that etches the semiconductor layers 122 at a faster etch rate than it etches the semiconductor layers 124, thus forming openings between neighboring semiconductor layers 124. In this way, the semiconductor layers 124 become nanosheets suspended over the substrate 110. This operation is also called a channel release process. In some embodiments, the semiconductor layers 124 can be interchangeably referred to as nanostructure (nanowires, nanoslabs and nanorings, nanosheet, etc., depending on their geometry). For example, in some other embodiments the semiconductor layers 124 may be trimmed to have a substantial rounded shape (i.e., cylindrical) due to the selective etching process for completely removing the semiconductor layers 124. In that case, the resultant semiconductor layers 124 can be called nanowires.

In some embodiments, the semiconductor layers 122 are removed by using a selective dry etching process by using, for example, CF₄ as etching gases. In some embodiments, the semiconductor layers 122 are SiGe and the semiconductor layers 124 are silicon allowing for the selective removal of the semiconductor layers 122.

Interfacial layers 212 are then formed around the semiconductor layers 124. In some embodiments, the interfacial layer 212 may include a dielectric material such as silicon oxide (SiO₂), HfSiO, or silicon oxynitride (SiON). The interfacial layers 212 may be formed by chemical oxidation, thermal oxidation, atomic layer deposition (ALD), chemical vapor deposition (CVD), and/or other suitable method. In some embodiments, when the interfacial layers 212 are formed by oxidation, the interfacial layers 212 are grown on the surfaces of semiconductor materials, such as the semiconductor layers 124.

Thereafter, high-k gate dielectric layers 214 are formed to cover the interfacial layers 212. The high-k gate dielectric layer 214 of the gate dielectric layer may include hafnium oxide (HfO₂). Alternatively, the high-k gate dielectric layer 214 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The high-k gate dielectric layers 214 may be formed by atomic layer deposition (ALD), chemical vapor deposition (CVD), and/or other suitable method.

Next, a gate electrode 216 is deposited in the gate trenches and fills the gate trenches. The gate electrode 216 may include one or more work function metals to provide a suitable work function for (metal) gate structures 210. For a p-type FET, the gate electrode 216 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. For an n-type FET, the gate electrode 216 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. The gate electrode 216 may be formed by atomic layer deposition (ALD), chemical vapor deposition (CVD), and/or other suitable method. Subsequently, one or more CMP processes are performed to remove excessive gate materials. Therefore, the interfacial layers 212, the high-k gate dielectric layers 214, and the gate electrode 216 form (metal) gate structures 210.

Reference is made to FIG. 6. An etch stop layer 220 and an ILD layer 225 are formed over the structure as shown in FIG. 5. Materials, configurations, dimensions, processes and/or operations regarding the etch stop layer 220 are similar to or the same as the CESL 180 described in FIG. 4, and materials, configurations, dimensions, processes and/or operations regarding the ILD layer 225 are similar to or the same as the ILD layer 185 described in FIG. 4. Subsequently, openings are formed in the ILD layers 225, 185 (see FIG. 5) and the etch stop layer 220. The opening exposes the source/drain epitaxial structures 175. Dielectric liners 230 are formed in the openings. In some embodiments, the dielectric liners 230 include silicon nitride layers, silicon oxide layers, silicon oxynitride layers, and/or other suitable materials.

Front-side metal alloy layers 240 are then respectively formed above the source/drain epitaxial structures 175. The front-side metal alloy layers 240, which may be silicide layers, are respectively formed over the exposed source/drain epitaxial structures 175 by a self-aligned silicide (salicide) process. The silicide process converts the surface portions of the source/drain epitaxial structures 175 into the silicide contacts. In some embodiments, the front-side metal alloy layer 240 may include germanium.

Front-side source/drain contacts 245 are then respectively formed in the openings and on the front-side metal alloy layers 240. Each of the front-side source/drain contacts 245 is connected to the corresponding source/drain epitaxial structure 175. Formation of the front-side source/drain contacts 245 includes depositing one or more conductive (e.g., metal) materials overfilling the openings and then performing a CMP process to remove excessive metal materials outside the openings.

After the formation of the front-side source/drain contacts 245, an etch stop layer 250 and an ILD layer 255 are formed over the ILD layer 225 and the front-side source/drain contacts 245. Materials, configurations, dimensions, processes and/or operations regarding the etch stop layer 250 are similar to or the same as the CESL 180 described in FIG. 4, and materials, configurations, dimensions, processes and/or operations regarding the ILD layer 255 are similar to or the same as the ILD layer 185 described in FIG. 4. In some embodiments, a front-side interconnect structure is formed over the etch stop layer 250 and the ILD layer 255, and one or more conductive lines and vias in the front-side interconnect structure are electrically connected to the front-side source/drain contacts 245.

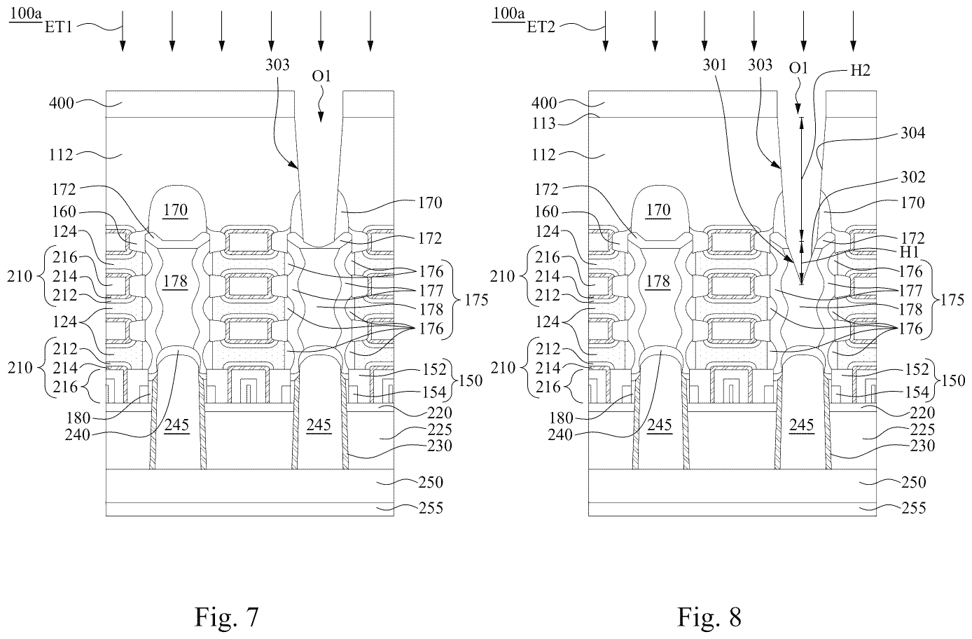

Reference is made to FIG. 7. The structure in FIG. 6 is flipped upside down, such that a backside surface of the substrate 110 faces upwards. The substrate 110 is thinned down or removed to expose the bottom surface of the isolation structure 130 (see FIG. 2A) and the semiconductor base portion 112. In some embodiments, thinning is accomplished by a CMP process, a grinding process, or the like.

A top part 303 of at least one opening O1 is formed in the semiconductor base portion 112. Specifically, a mask layer 400 is formed on a backside of the semiconductor base portion 112, and a first etching process ET1 is performed to form the top part 303 of opening O1. The first etching process ET1 may be an anisotropic dry etching process using a time mode to determine the shape and the depth of the top part 303 of the opening O1. That is, the first etching process ET1 etches in a vertical direction at a rate faster than it etches in a lateral direction. In some embodiments, the first etching process ET1 is performed using an etching gas including HS₄ and CF₄. In some embodiments, a flow rate of the etching gas during the first etching process ET1 is in a range of about 200 sccm to about 500 sccm. The top part 303 of the opening O1 tapers toward the source/drain epitaxial structures 175 and may be stopped near the dielectric layer 172. That is, the top part 303 of the opening O1 passes through the bottom semiconductor structure 170 to the dielectric layer 172. As shown in FIG. 7, the bottom semiconductor structure 170 laterally surrounds the top part 303 of the opening O1, and the top part 303 of the opening O1 exposes the bottom semiconductor structure 170.

Reference is made to FIG. 8. A second etching process ET2 is performed to form a bottom part 301 of the opening O1. In some embodiments, the second etching process ET2 is performed using an etching gas including NF₂ and Cl₂. In some embodiments, a flow rate of the etching gas during the second etching process ET2 is in a range of about 100 sccm to about 200 sccm. The bottom part 301 of the opening O1 extends deep into the third semiconductor portion 178 of the source/drain epitaxial structure 175. As shown in FIG. 8, a bottom sidewall 302 of the opening O1 and a top sidewall 304 of the opening O1 have different slopes. The bottom sidewall 302 of the opening O1 is more inclined relative to a backside surface 113 of the semiconductor base portion 112 than the top sidewall 304 of the opening O1 is. Stated another way, the tapering gradient of the bottom part 301 of the opening O1 is steeper than the tapering gradient of the top part 303 of the opening O1. Also, the rate at which the bottom part 301 narrows or reduces in dimension in a vertical direction (i.e., Z direction in this case) is higher than the rate at which the top part 303 narrows or reduces in dimension in the vertical direction. In some embodiments, the bottom part 301 of the opening O1 has a V-shape end in the cross-sectional view. Further, a height H1 of the bottom part 301 of the opening O1 is less than a height H2 of the top part 303 of the opening O1. Therefore, the opening O1 extends deep into the third semiconductor portion 178 while minimizing the removal of the epitaxial materials of the third semiconductor portion 178. The electrical resistance of the third semiconductor portion 178 increases as the size of the third semiconductor portion 178 decreases. The bottom part 301 of the opening O1 has a sharp tip as shown in FIG. 8.

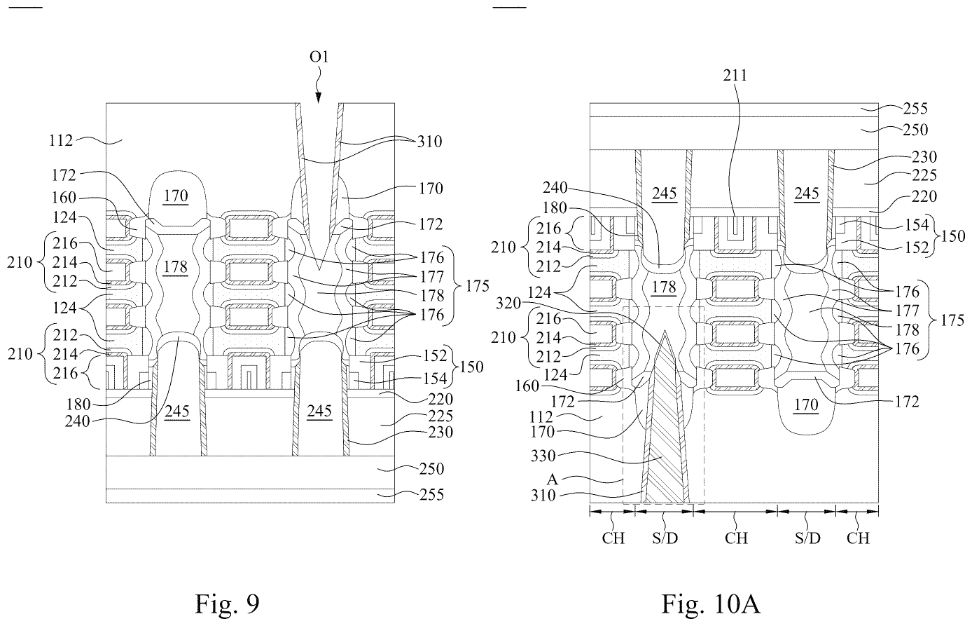

Reference is made to FIG. 9. The mask layer 400 in FIG. 8 is removed. Spacer structures 310 are then formed to line sidewalls of the opening O1. The formation of the spacer structures 310 may include blanket forming spacer layers and then performing etching operations to remove the horizontal portion and/or the bottom portion of the spacer layers. The remaining vertical portion of the spacer layer forms the spacer structure 310. The spacer structure 310 includes one or more dielectric materials, such as silicon oxide, silicon nitride, silicon oxynitride, SiCN, SiCₓO_{y}N_{z}, high-k dielectric materials, or combinations thereof. The spacer structure 310 can be formed using a deposition method, such as plasma enhanced chemical vapor deposition (PECVD), plasma enhanced atomic layer deposition (PEALD), or the like.

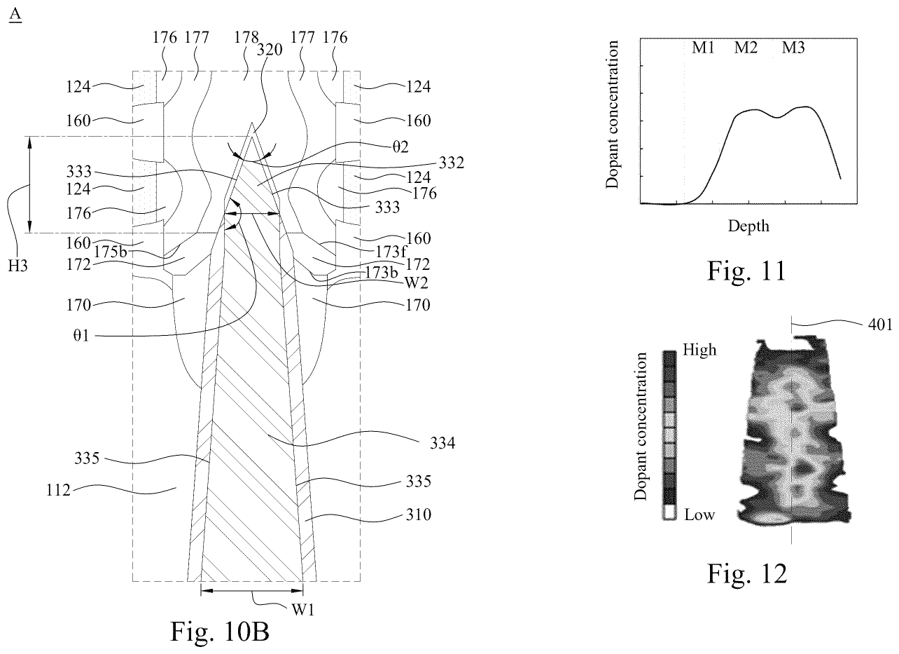

Reference is made to FIGS. 10A and 10B, where FIG. 10B is an enlarged view of area A in FIG. 10A. Optionally, a backside metal alloy layer 320 is formed in the opening O1 (see FIG. 9) and on the exposed portion of the source/drain epitaxial structure 175. Materials, configurations, dimensions, processes and/or operations regarding the backside metal alloy layer 320 are similar to or the same as the front-side metal alloy layer 240 described in FIG. 6.

At least one backside source/drain contact 330 is formed in the opening O1 and covers the backside metal alloy layer 320. Formation of the backside source/drain contact 330 includes depositing one or more metal materials overfilling the opening O1, and then performing a CMP process to remove excessive metal materials outside the opening O1. As shown in FIGS. 10A and 10B, the spacer structure 310 isolates the backside source/drain contact 330 from the semiconductor base portion 112 and the bottom semiconductor structure 170. After the formation of the backside source/drain contact 330, a backside interconnect structure may be formed at the backside of the structure shown in FIG. 10A, and at least one of the conductive lines and vias in the backside interconnect structure are electrically connected to the backside source/drain contact 330. Thereafter, the semiconductor device 100a is flipped again as shown in FIG. 10A.

In FIG. 10A, the semiconductor device 100a includes at least one transistor including channel structures (i.e., the semiconductor layers) 124 stacked over one another and arranged in a vertical direction (Z direction in this case), a gate structure 210 over (or covering or surrounding or wrapping) the channel structures 124, source/drain epitaxial structures 175 on opposite sides of the gate structure 210 and connected to the channel structures 124. The semiconductor device 100a further includes a backside source/drain contact 330 under and connected to the source/drain epitaxial structure 175. Specifically, the backside source/drain contact 330 extends into the source/drain epitaxial structure 175 from a backside of the source/drain epitaxial structure 175.

As shown in FIGS. 10A and 10B, the backside source/drain contact 330 includes first portion 332 and a second portion 334 connected to the first portion 332. The first portion 332 is embedded in the third semiconductor portion 178 of the source/drain epitaxial structure 175 and the second portion 334 is embedded in the semiconductor base portion 112 and the bottom semiconductor structure 170. An interface between the first portion 332 and the second portion 334 is at a level lower than a position of the bottommost channel structure 124. The first portion 332 and the second portion 334 both taper toward the source/drain epitaxial structure 175 but with different tapering gradients. Therefore, the backside source/drain contact 330 is shaped like a multi-stage (e.g., two stages) tapered pillar. A maximum width W1 of the second portion 334 is greater than a maximum width W2 of the first portion 332. Further, a variation in width of the first portion 332 is greater than a variation in width of the second portion 334. Stated another way, sidewalls 333 of the first portion 332 and sidewalls 335 of the second portion 334 have different slopes. The sidewalls 333 of the first portion 332 are more inclined relative to a reference horizontal surface (e.g., a top surface 211 of the gate structure 210 or a top surface of dielectric layers) than the sidewalls 335 of the second portion 334 are.

With such configuration, the backside source/drain contact 330 improves the electrical performance of the semiconductor device 100a. In greater detail, FIG. 11 is a graph of a dopant concentration of the source/drain epitaxial structure in a depth direction, and FIG. 12 is a dopant concentration distribution of the source/drain epitaxial structure. In FIG. 11, the area M1 represents the position of the first semiconductor portions 176 and the second semiconductor portions 177, and the areas M2 and M3 represent the position of the third semiconductor portion 178. As shown in FIG. 11, the dopant concentration in the third semiconductor portion 178 is higher than that in the first semiconductor portions 176 and the second semiconductor portions 177, which means that the third semiconductor portion 178 has higher electrical conductivity than that of the first semiconductor portions 176 and the second semiconductor portions 177. FIG. 12 shows that the high dopant concentration region is near the middle line 401 of the source/drain epitaxial structures 175. Therefore, when the backside source/drain contact 330 is connected to the region near the middle line 401 of the source/drain epitaxial structures 175 and in the third semiconductor portion 178, the electrical performance of the backside source/drain contact 330 can be improved.

Reference is back to FIGS. 10A and 10B. The second portion 334 of the backside source/drain contact 330 has a wide width W1 with a minor variation in width, such that size of the backside source/drain contact 330 is large enough to be a good conductor. On the other hand, the first portion 332 of the backside source/drain contact 330 has a narrow width W2 with a significant variation in width, such that the first portion 332 can be deep into the third semiconductor portion 178 while the size of the third semiconductor portion 178 is not reduced too much during the second etching process ET2 (see FIG. 8). Further, since the first portion 332 of the backside source/drain contact 330 has the narrow width W2 with the significant variation in width, the backside source/drain contact 330 is far away from the channel structures 124, avoiding current crowding suppression issues occur between the channel structures 124 and the backside source/drain contact 330 and thus the saturation current of the semiconductor device 100a can be improved. For an SRAM device, the current crowding issue is related to the SRAM DC performance and the speed of cell operations. The backside source/drain contact 330 is further far away from the gate structure 210, avoiding the electrical short problem therebetween. In addition, the first portion 332 has a V-shape end in the cross-sectional view, and the tapering shape of the first portion 332 increases the contact area between the backside source/drain contact 330 and the backside metal alloy layer 320 (and thus the third semiconductor portion 178 of the source/drain epitaxial structure 175), lowering the electrical resistance therebetween.

The semiconductor device 100a further includes the dielectric layer 172 between the source/drain epitaxial structure 175 and the bottom semiconductor structure 170. For example, the dielectric layer 172 is in contact with a backside surface 175b of the source/drain epitaxial structure 175. A front-side surface 173f of the dielectric layer 172 faces the source/drain epitaxial structure 175, and a backside surface 173b of the dielectric layer 172 opposes the front-side surface 173f and faces the bottom semiconductor structure 170. The first portion 332 of the backside source/drain contact 330 is near the front-side surface 173f of the dielectric layer 172, and the second portion 334 of the backside source/drain contact 330 is near the backside surface 173b of the dielectric layer 172. The dielectric layer 172 prevents the dopants in the source/drain epitaxial structure 175 from leaking to the semiconductor base portion 112. During the formation of the opening O1 (see FIGS. 7-8), a portion of the dielectric layer 172 is removed, such that the dopants may be diffused to the semiconductor base portion 112 from the opening O1. Due to the tapered shaped of the second portion 334 of the backside source/drain contact 330, the opening O1 in the dielectric layer 172 is not so large, and the remaining portion of the dielectric layer 172 still blocks most of the dopants. Also, the spacer structures 310 are benefited to prevent the dopants from diffusion. Even some of the dopants are diffused out of the dielectric layer 172, the bottom semiconductor structure 170 can act to be a blocker, too. As such, the shape of the second portion 334 of the backside source/drain contact 330 improves the dopant diffusion issue of the source/drain epitaxial structure 175 and improves overall yield.

As shown in FIG. 10B, in some embodiments, an angle θ1 is formed between the adjacent sidewalls 333 and 335, and the angle θ1 is in a range of about 100 degrees and about 160 degrees. If the angle θ1 is less than about 100 degrees, the contact area between the backside source/drain contact 330 and the backside metal alloy layer 320 (and thus the third semiconductor portion 178) is small, and the first portion 332 of the backside source/drain contact 330 is not deep enough into the source/drain epitaxial structure 175; if the angle θ1 is greater than about 160 degrees, the first portion 332 of the backside source/drain contact 330 may be too close to the gate structure 210 and/or the channel structures 124.

In some embodiments, a top of the backside source/drain contact 330 has an angle θ2 (defined by the sidewalls 335) in a range of about 30 degrees and about 60 degrees. If the angle θ2 is less than about 30 degrees, the electrical contact between the backside source/drain contact 330 and the source/drain epitaxial structure 175 may be poor; if the angle θ2 is greater than about 60 degrees, the size of the first portion 332 of the backside source/drain contact 330 may be too large, and the source/drain epitaxial structure 175 may suffer huge loss during the second etching process ET2 (see FIG. 8).

In some embodiments, a portion of the backside source/drain contact 330 embedded in (the third semiconductor portion 178 of) the source/drain epitaxial structure 175 has a height (or vertical thickness) H3 in a range of about 2 nm and about 10 nm. If the height H3 is less than about 2 nm, the backside source/drain contact 330 is not deep enough into the source/drain epitaxial structure 175; if the height H3 is greater than about 10 nm, the source/drain epitaxial structure 175 may suffer huge loss during the second etching process ET2 (see FIG. 8).

In some embodiments, a ratio of the height H3 and the pitch SS (denoted in FIG. 2B) between the channel structures 124 is in a range of about 0.5 and about 1. If the ratio is less than about 0.5, the backside source/drain contact 330 is not deep enough into the source/drain epitaxial structure 175; if the ratio is greater than about 1, the source/drain epitaxial structure 175 may suffer huge loss during the second etching process ET2 (see FIG. 8).

As shown in FIGS. 10A and 10B, the spacer structures 310 laterally surround the second portion 334 of the backside source/drain contact 330 but spaced apart from the first portion 332 of the backside source/drain contact 330. The dielectric layer 172 is under the source/drain epitaxial structure 175, and the bottom semiconductor structure 170 is under the dielectric layer 172 and the source/drain epitaxial structure 175. The bottom semiconductor structure 170 and the dielectric layer 172 laterally surround the second portion 334 of the backside source/drain contact 330 but spaced apart from the first portion 332 of the backside source/drain contact 330.

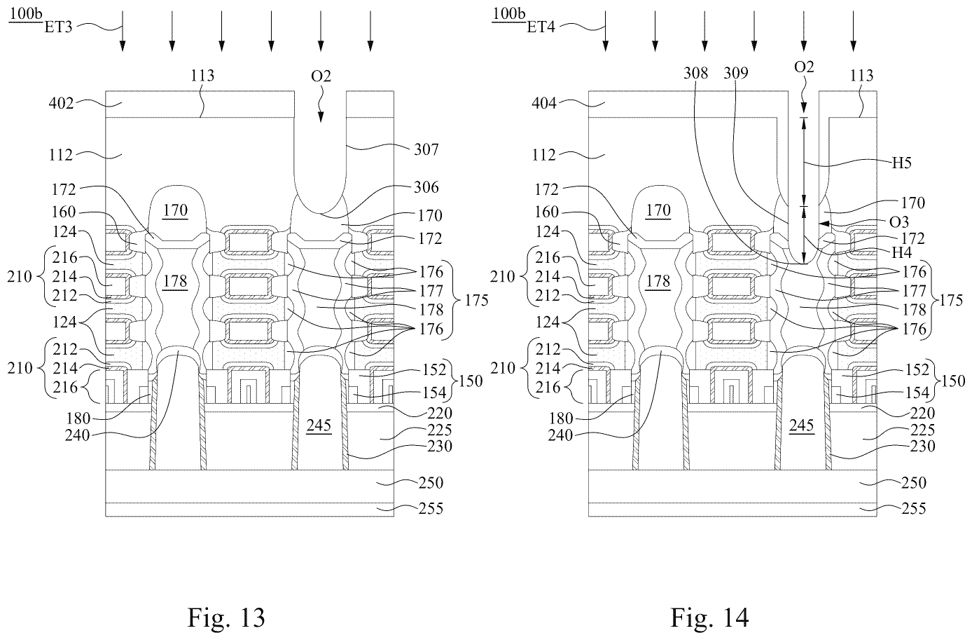

FIGS. 13-16B are cross-sectional view of an integrated circuit structure (or a semiconductor device) 100b in accordance with some embodiments of the present disclosure. In some embodiments, the shape of the backside source/drain contact 330 may have a round top. For example, in FIG. 13, after the process as shown in FIG. 6 is performed, the structure in FIG. 6 is flipped upside down, and the substrate 110 is thinned down or removed to expose the bottom surface of the isolation structure 130 (see FIG. 2A) and the semiconductor base portions 112.

At least one opening O2 is formed in the semiconductor base portion 112. Specifically, a mask layer 402 is formed on a backside of the semiconductor base portion 112, and a first etching process ET3 is performed to form the opening O2. The first etching process ET3 may be an anisotropic dry etching process using a time mode to determine the shape and the depth of the opening O2. That is, the first etching process ET3 etches in a vertical direction at a rate faster than it etches in a lateral direction. In some embodiments, the first etching process ET3 is performed using an etching gas including CH₄ and F₂. In some embodiments, a flow rate of the etching gas during the first etching process ET3 is in a range of about 100 sccm to about 200 sccm. The opening O2 extends toward the source/drain epitaxial structures 175 and may be stopped near the bottom semiconductor structure 170. That is, the opening O1 passes through the semiconductor base portion 112 to the bottom semiconductor structure 170. As shown in FIG. 13, the semiconductor base portion 112 laterally surrounds the opening O2, and the opening O2 exposes the semiconductor base portion 112 and the bottom semiconductor structure 170. In some embodiments, the opening O2 has sidewalls 307 and a bottom surface 306 connected to the sidewalls 307. The sidewalls 307 are substantially linear and may be substantially vertical relative to a backside surface 113 of the semiconductor base portion 112, and the bottom surface 306 is curved.

Reference is made to FIG. 14. The mask layer 402 is removed, and another mask layer 404 is formed over the backside of the semiconductor base portion 112. As shown in FIG. 14, portions of the mask layer 404 is in the opening O2. A second etching process ET4 is performed to form an opening O3 under the opening O2. In some embodiments, the second etching process ET4 is performed using an etching gas including SF₆ and Cl₂. In some embodiments, a flow rate of the etching gas during the second etching process ET2 is in a range of about 100 sccm to about 200 sccm. The opening O3 extends deep into the third semiconductor portion 178 of the source/drain epitaxial structure 175. As shown in FIG. 14, the opening O3 has sidewalls 309 and a bottom surface 308 connected to the sidewalls 309. The sidewalls 309 are substantially linear and may be substantially vertical relative to a backside surface 113 of the semiconductor base portion 112, and the bottom surface 308 is curved (e.g., concave). Further, a height H4 of the opening O3 is less than a height H5 of the opening O2. Therefore, the opening O3 extends deep into the third semiconductor portion 178 while minimizing the removal of the epitaxial materials of the third semiconductor portion 178.

Reference is made to FIG. 15. The mask layer 404 in FIG. 14 is removed. Spacer structures 315 are formed on inner sidewalls of the openings O2 and O3. The formation of the spacer structures 315 may include blanket forming spacer layers and then performing etching operations to remove the horizontal portion and/or the bottom portion of the spacer layers. The remaining vertical portion of the spacer layer forms the spacer structure 315. The spacer structure 315 includes one or more dielectric materials, such as silicon oxide, silicon nitride, silicon oxynitride, SiCN, SiCₓO_{y}N_{z}, high-k dielectric materials, or combinations thereof. The spacer structure 315 can be formed using a deposition method, such as plasma enhanced chemical vapor deposition (PECVD), plasma enhanced atomic layer deposition (PEALD), or the like.

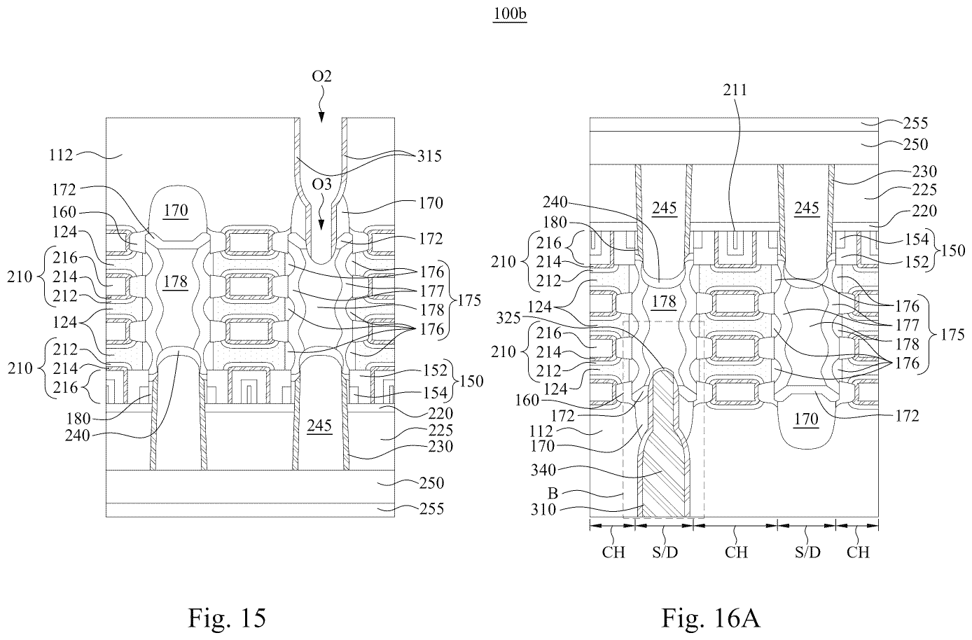

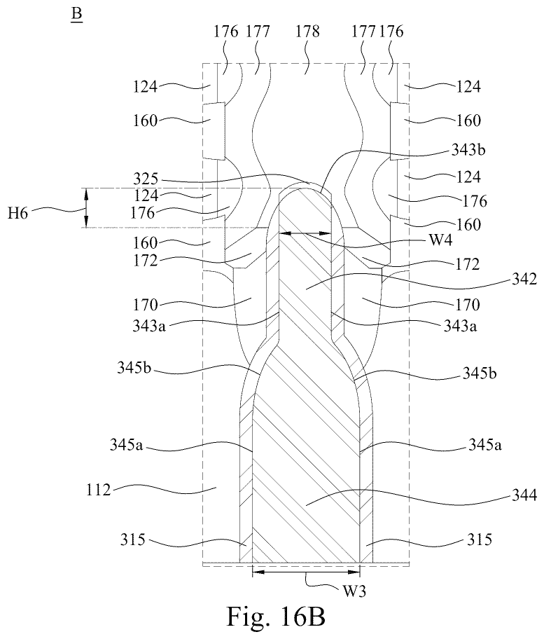

Reference is made to FIGS. 16A and 16B, where FIG. 16B is an enlarged view of area B in FIG. 16A. Optionally, a backside metal alloy layer 325 is formed in the opening O3 (see FIG. 12) and on the exposed portion of the source/drain epitaxial structure 175. Materials, configurations, dimensions, processes and/or operations regarding the backside metal alloy layer 325 are similar to or the same as the front-side metal alloy layer 240 described in FIG. 6.

At least one backside source/drain contact 340 is formed in the openings O2 and O3 (see FIG. 12) and covers the backside metal alloy layer 325. Formation of the backside source/drain contact 340 includes depositing one or more metal materials overfilling the openings O2 and O3, and then performing a CMP process to remove excessive metal materials outside the openings O2 and O3. As shown in FIGS. 16A and 16B, the spacer structure 315 isolates the backside source/drain contact 340 from the semiconductor base portion 112 and the bottom semiconductor structure 170. After the formation of the backside source/drain contact 340, a backside interconnect structure may be formed at the backside of the structure shown in FIG. 16A, and at least one of the conductive lines and vias in the backside interconnect structure are electrically connected to the backside source/drain contact 340. Thereafter, the semiconductor device 100b is flipped again as shown in FIG. 16A.

In FIG. 16A, the semiconductor device 100b includes at least one transistor including channel structures (i.e., the semiconductor layers) 124 stacked over one another and arranged in a vertical direction (Z direction in this case), a gate structure 210 over (or covering or surrounding or wrapping) the channel structures 124, source/drain epitaxial structures 175 on opposite sides of the gate structure 210 and connected to the channel structures 124. The semiconductor device 100b further includes a backside source/drain contact 340 under and connected to the source/drain epitaxial structure 175. Specifically, the backside source/drain contact 340 extends into the source/drain epitaxial structure 175 from a backside of the source/drain epitaxial structure 175.

As shown in FIGS. 16A and 16B, the backside source/drain contact 340 includes first portion 342 and a second portion 344 connected to the first portion 342. The first portion 342 is between the second portion 344 and the source/drain epitaxial structure 175. The first portion 342 extends into the source/drain epitaxial structure 175 and has linear sidewalls 343a and a curved surface 343b. The second portion 344 has linear sidewalls 345a and curved surfaces 345b. Each of the curved surfaces 345b of the second portion 344 interconnects one of the linear sidewalls 343a and one of the linear sidewalls 345a. Further, the linear sidewalls 343a are between the curved surface 343b and the corresponding curved surfaces 345b. Both the curved surfaces 343b and 345b are convex. Therefore, the first portion 342 has a U-shape end in a cross-sectional view.

The semiconductor base portion 112 laterally surrounds the second portion 334, and the bottom semiconductor structure 170 laterally surrounds the first portion 332. The second portion 344 of the backside source/drain contact 340 is spaced apart from the source/drain epitaxial structure 175. The second portion 344 has a width W3 greater than a width W4 of the first portion 342. Therefore, the backside source/drain contact 340 is shaped like a multi-stage (e.g., two stages) pillar or a funnel.

With such configuration, the backside source/drain contact 340 improves the electrical performance of the semiconductor device 100b. The second portion 344 of the backside source/drain contact 340 has a wide width W3, such that size of the backside source/drain contact 340 is large enough to be a good conductor. On the other hand, the first portion 342 of the backside source/drain contact 340 has a narrow width W4, such that the first portion 342 extends deep into the third semiconductor portion 178 while the size of the third semiconductor portion 178 is not reduced too much during the second etching process ET4 (see FIG. 14). Further, since the first portion 342 of the backside source/drain contact 340 has the narrow width W4, the backside source/drain contact 340 is far away from the channel structures 124, avoiding current crowding suppression issues occur between the channel structures 124 and the backside source/drain contact 340 and thus the saturation current of the semiconductor device 100b can be improved. The backside source/drain contact 340 is further far away from the gate structure 210, avoiding the electrical short problem therebetween. In addition, the curved top shape of the first portion 342 increases the contact area between the backside source/drain contact 340 and the backside metal alloy layer 325 (and thus the third semiconductor portion 178 of the source/drain epitaxial structure 175), lowering the electrical resistance therebetween.

The semiconductor device 100b further includes the dielectric layer 172 between the source/drain epitaxial structure 175 and the bottom semiconductor structure 170. During the formation of the opening O3 (see FIG. 14), a portion of the dielectric layer 172 is removed, such that the dopants may be diffused to the semiconductor base portion 112 from the opening O3. Due to the narrow width of the first portion 342 of the backside source/drain contact 340, the opening O3 in the dielectric layer 172 is not so large, and the remaining portion of the dielectric layer 172 still blocks most of the dopants. Also, the spacer structures 315 are benefited to prevent the dopants from diffusion. Even some of the dopants are diffused out of the dielectric layer 172, the bottom semiconductor structure 170 can act to be a blocker, too. As such, the shape of the first portion 342 of the backside source/drain contact 340 improves the dopant diffusion issue of the source/drain epitaxial structure 175 and improves overall yield.

In some embodiments, a ratio of the width W4 to the width W3 is in a range of about 0.3 and about 0.8. If the ratio is less than about 0.3, the size of the first portion 342 may be too small and the electrical contact between the backside source/drain contact 340 and the source/drain epitaxial structure 175 may be poor; if the ratio is greater than about 0.8, the size of the first portion 342 may be too large, and the source/drain epitaxial structure 175 may suffer huge loss during the second etching process ET4 (see FIG. 14).

In some embodiments, a portion of the backside source/drain contact 340 embedded in the (third semiconductor portion 178 of the) source/drain epitaxial structure 175 has a height (or vertical thickness) H6 in a range of about 2 nm and about 10 nm. If the height H6 is less than about 2 nm, the backside source/drain contact 340 is not deep enough into the source/drain epitaxial structure 175; if the height H6 is greater than about 10 nm, the source/drain epitaxial structure 175 may suffer huge loss during the second etching process ET4 (see FIG. 14).

In some embodiments, a ratio of the height H6 and the pitch SS (denoted in FIG. 2B) between the channel structures 124 is in a range of about 0.5 and about 1. If the ratio is less than about 0.5, the backside source/drain contact 340 is not deep enough into the source/drain epitaxial structure 175; if the ratio is greater than about 1, the source/drain epitaxial structure 175 may suffer huge loss during the second etching process ET4 (see FIG. 14).

As shown in FIGS. 16A and 16B, the dielectric layer 172 is under the source/drain epitaxial structure 175, and the bottom semiconductor structure 170 is under the dielectric layer 172 and the source/drain epitaxial structure 175. The dielectric layer 172 laterally surrounds the first portion 342 of the backside source/drain contact 340 but spaced apart from the second portion 344 of the backside source/drain contact 340. The bottom semiconductor structure 170 laterally surrounds the first portion 342 of the backside source/drain contact 340.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the funnel-shaped backside source/drain contact improves the current crowding issues between the backside source/drain contact and the channel structures, and also improves electrical short issues between the backside source/drain contact and the gate structure. Moreover, the contact area between the backside source/drain contact and the backside metal alloy layer is increased, lowering the electrical resistance therebetween. Furthermore, the diffusion of the dopants in the source/drain epitaxial structure can be suppressed. In addition, the configuration of the backside source/drain contact avoids the source/drain epitaxial structure suffers huge loss during the etching process for forming the backside source/drain contact.

According to some embodiments, a device includes a channel structure, a gate structure, a first source/drain epitaxial structure, a second source/drain epitaxial structure, and a backside source/drain contact. The gate structure covers the channel structure. The first source/drain epitaxial structure and the second source/drain epitaxial structure are on opposite sides of the gate structure and connected to the channel structure. The backside source/drain contact is under and connected to the first source/drain epitaxial structure. The backside source/drain contact includes a first portion embedded in the first source/drain epitaxial structure and a second portion connected to the first portion. A sidewall of the first portion and a sidewall of the second portion have different slopes.

According to some embodiments, a device includes a plurality of channel structures, a first source/drain epitaxial structure, a second source/drain epitaxial structure, a gate structure, and a backside source/drain contact. The channel structures are stacked over one another. The first source/drain epitaxial structure and the second source/drain epitaxial structure are connected to the channel structures. The gate structure surrounds the channel structures and is between the first source/drain epitaxial structure and the second source/drain epitaxial structure. The backside source/drain contact extends into the first source/drain epitaxial structure from a backside of the first source/drain epitaxial structure. The backside source/drain contact includes a first portion and a second portion. The first portion extends into the first source/drain epitaxial structure and has a first linear sidewall and a first curved surface. The second portion has a second linear sidewall and a second curved surface. The first portion is between the second portion and the first source/drain epitaxial structure, and the second curved surface interconnects the first linear sidewall and the second linear sidewall.

According to some embodiments, a method includes forming a transistor over a substrate. The transistor includes a channel layer over the substrate, a gate structure over the substrate and the channel layer, and a first source/drain epitaxial structure and a second source/drain epitaxial structure on opposite sides of the channel layer. The method further includes thinning down the substrate until a semiconductor base portion of the substrate is exposed. A first etching process is performed to form a top part of an opening in the semiconductor base portion. A second etching process is performed to form a bottom part of the opening in the first source/drain epitaxial structure. A backside source/drain contact is formed in the opening. A tapering gradient of the bottom part of the opening is steeper than a tapering gradient of the top part of the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a channel structure;
a gate structure covering the channel structure;
a first source/drain epitaxial structure and a second source/drain epitaxial structure on opposite sides of the gate structure and connected to the channel structure; and
a backside source/drain contact under and connected to the first source/drain epitaxial structure, wherein the backside source/drain contact comprises:
a first portion embedded in the first source/drain epitaxial structure; and
a second portion connected to the first portion, wherein a sidewall of the first portion and a sidewall of the second portion have different slopes.

2. The device of claim 1, wherein the first portion has a V-shape end in a cross-sectional view.

3. The device of claim 1, wherein an angle of a top of the first portion is in a range of about 30 degrees and about 60 degrees.

4. The device of claim 1, wherein the second portion tapers toward the first source/drain epitaxial structure.

5. The device of claim 1, wherein a variation in width of the first portion is greater than a variation in width of the second portion.

6. The device of claim 1, further comprising a spacer structure laterally surrounding the second portion of the backside source/drain contact.

7. The device of claim 6, wherein the spacer structure is spaced apart from the first portion of the backside source/drain contact.

8. The device of claim 1, further comprising a dielectric layer in contact with a backside surface of the first source/drain epitaxial structure, wherein a front-side surface of the dielectric layer faces the first source/drain epitaxial structure, and a backside surface of the dielectric layer opposes the front-side surface, the first portion of the backside source/drain contact is near the front-side surface of the dielectric layer, and the second portion of the backside source/drain contact is near the backside surface of the dielectric layer.

9. The device of claim 1, wherein the first source/drain epitaxial structure comprises:
a first semiconductor portion connected to the channel structure;
a second semiconductor portion connected to the first semiconductor portion; and
a third semiconductor portion connected to the second semiconductor portion, wherein a dopant concentration of the third semiconductor portion is higher than a dopant concentration of the second semiconductor portion, and the first portion of the backside source/drain contact is embedded in the third semiconductor portion.

10. A device comprising:
a plurality of channel structures stacked over one another;
a first source/drain epitaxial structure and a second source/drain epitaxial structure connected to the channel structures;
a gate structure surrounding the channel structures and between the first source/drain epitaxial structure and the second source/drain epitaxial structure; and
a backside source/drain contact extending into the first source/drain epitaxial structure from a backside of the first source/drain epitaxial structure, wherein the backside source/drain contact comprises:
a first portion extending into the first source/drain epitaxial structure and has a first linear sidewall and a first curved surface; and
a second portion having a second linear sidewall and a second curved surface, wherein the first portion is between the second portion and the first source/drain epitaxial structure, and the second curved surface interconnects the first linear sidewall and the second linear sidewall.

11. The device of claim 10, wherein a width of the second portion is greater than a width of the first portion.

12. The device of claim 10, wherein the first linear sidewall is between the first curved surface and the second curved surface.

13. The device of claim 10, wherein the first curved surface is convex.

14. The device of claim 10, wherein the second curved surface is convex.

15. The device of claim 10, wherein the second portion of the backside source/drain contact is spaced apart from the first source/drain epitaxial structure.

16. The device of claim 10, further comprising a dielectric layer under the first source/drain epitaxial structure, wherein the dielectric layer laterally surrounds the first portion of the backside source/drain contact.

17. The device of claim 10, further comprising a bottom semiconductor structure under the first source/drain epitaxial structure and laterally surrounds the first portion of the backside source/drain contact.

18. A method comprising:
forming a transistor over a substrate, wherein the transistor comprises:
a channel layer over the substrate;
a gate structure over the substrate and the channel layer; and
a first source/drain epitaxial structure and a second source/drain epitaxial structure on opposite sides of the channel layer;
thinning down the substrate until a semiconductor base portion of the substrate is exposed;
performing a first etching process to form a top part of an opening in the semiconductor base portion;
performing a second etching process to form a bottom part of the opening in the first source/drain epitaxial structure, wherein a tapering gradient of the bottom part of the opening is steeper than a tapering gradient of the top part of the opening; and
forming a backside source/drain contact in the opening.

19. The method of claim 18, wherein the bottom part of the opening has a V-shape end in a cross-sectional view.

20. The method of claim 18, wherein a sidewall of the bottom part of the opening is more inclined relative to a backside surface of the semiconductor base portion than a sidewall of the top part of the opening is.
